(19) United States
(12) Patent Application Publication
(10) Pub. No.: US 2008/0149970 A1
(43) Pub. Date: Jun. 26, 2008

(54) Multi-gated carbon nanotube field effect transistor

(76) Inventors: Shawn G. Thomas, Gilbert, AZ (US); Islamshah S. Amlani, Chandler, AZ (US)

Correspondence Address: INGRASSIA FISHER & LORENZ, P.C. (MOT), 7010 E. Cochise Road, SCOTTSDALE, AZ, 85253, US

(21) Appl. No.: 11/643,434

(22) Filed: Dec. 21, 2006

(51) Int. Cl. H01L 27/00; H01L 21/762

(52) U.S. Cl. 257/288; 438/197; 977/742; 257/E21.545

(57) ABSTRACT

A multiple, independent top gated field effect transistor having an improved electron injection and reduced gate induced barrier lowering effects, and a method that allows for the destruction of metallic carbon nanotubes positioned between the source and drain of a top multi-gate transistor are provided. The field effect transistor comprises at least one carbon nanotube (14) coupled between the first and second electrodes (16, 18) and a first gate material (24) formed over a portion of the at least one carbon nanotube (14) and spaced apart from the first and second electrodes (16, 18). A dielectric material (32) is conformally coated on the first and second electrodes (16, 18), the at least one carbon nanotube (14), and the first gate material (24). A second gate material (36) is conformally coated on the dielectric material (32). Other exemplary embodiments include one gate (24, 36), three gates (24, 46, 48), and three gates (24, 54, 56; and 24, 66) having the dielectric layer (52, 56; and 62, 64) portioned with different material characteristics.

### FIELD OF THE INVENTION

The present invention generally relates to field effect transistors and more particularly to a multiple, independent top gated field effect transistor having an improved electron injection and a method that allows for the destruction of metallic carbon nanotubes positioned between the source and drain of a top multi-gate transistor.

### BACKGROUND OF THE INVENTION

One-dimensional nanostructures, such as belts, rods, tubes and wires, have become the focus of intensive research with their own unique applications. One-dimensional nanostructures are model systems to investigate the dependence of electrical and thermal transport or mechanical properties as a function of size reduction. In contrast with zero-dimensional, e.g., quantum dots, and two-dimensional nanostructures, e.g., GaAs/AlGaAs superlattice, direct synthesis and growth of one-dimensional nanostructures has been relatively slow due to difficulties associated with controlling the chemical composition, dimensions, and morphology. Alternatively, various one-dimensional nanostructures have been fabricated using a number of advanced nanolithographic techniques, such as electron-beam (e-beam), focused-ion-beam (FIB) writing, and scanning probe.

Carbon nanotubes are one of the most important species of one-dimensional nanostructures. Carbon nanotubes are one of four unique crystalline structures for carbon, the other three being diamond, graphite, and fullerene. In particular, carbon nanotubes refer to a helical tubular structure grown with a single wall (single-walled nanotubes) or multiple walls (multi-walled nanotubes). These types of structures are obtained by rolling a sheet formed of a plurality of hexagons. The sheet is formed by combining each carbon atom thereof with three neighboring carbon atoms to form a helical tube. Carbon nanotubes typically have a diameter on the order of a fraction of a nanometer to a few hundred nanometers. As used herein, a “carbon nanotube” in any elongated carbon structure.

Both carbon nanotubes and inorganic nanowires have been demonstrated as field effect transistors (FETs) and other basic components in nanoscale electronics such as p-n junctions, bipolar junction transistors, inverters, etc. The motivation behind the development of such nanoscale components is that “bottom-up” approach to nanoelectronics has the potential to go beyond the limits of the traditional “top-down” manufacturing techniques.

Unlike other inorganic one-dimensional nanostructures, carbon nanotubes can function as either a conductor, or a semiconductor, according to the chirality and the diameter of the helical tubes. With metallic-like nanotubes, a one-dimensional carbon-based structure can conduct a current at room temperature with essentially no resistance. Further, electrons can be considered as moving freely through the structure, so that metallic-like nanotubes can be used as ideal interconnects. When semiconductor nanotubes are connected to two metal electrodes, the structure can function as a field effect transistor wherein the nanotubes can be switched from a conducting to an insulating state by applying a voltage to a gate electrode. Therefore, carbon nanotubes are potential building blocks for nanoelectronic and sensor devices because of their unique structural, physical, and chemical properties.

As carbon nanotube field effect transistors are reduced in size, and the gate oxide thickness is reduced, a lower on/off ratio is experienced at typical drain voltages. This limits the range of usuable drain voltages and the achievable on currents. It has been shown that an asymmetric design can suppress an ambipolar transport characteristic of a Schottky barrier carbon nanotube field effect transistor depending on the drain voltage. Therefore, the turn-on performance may be dictated by the geometry of the contact and gate at the source electrode. This leads to larger on currents by preventing an increase in current with a larger drain voltage. The advantage of an asymmetric geometry also applies to ohmic contact carbon nanotube field effect transistors.

Single carbon nanotube FETs are typically either back gated or top gated. For any digital or analog application, the availability of a top gated nanotube FETs is critical. Top gated carbon nanotube FETs have been fabricated in geometries where the gate electrode either underlaps or overlaps source drain regions. Fabrication typically comprises patterning a gate on top of the nanotube channel where the gate dielectric underneath the gate metal coats either only under the gate or along the entire length of the nanotube.

It has been shown that improving electron injection efficiency into the channel region requires strong gate to source fields (where the source is typically grounded). This can be achieved by using a high-K dielectric for the gate dielectric and/or using a gate geometry that is in close proximity to the source. Typically, this is achieved by forming a slight overlap between gate and source/drain. However, stronger capacitive coupling between the gate and drain will reduce the barrier for minority carrier injection on the drain side (referred to as gate-induced-barrier-lowering (GIBL)) and result in inferior performance such as reduced ON/OFF current ratio and ambipolar transport. For good device performance it is critical to provide both improved electron injection efficiency and immunity against GIBL effects.

While normalized transconductance of a single nanotube FET can be quite large, the overall transconductance is small due to the intrinsic small size of the nanotube. Unlike conventional technologies, transconductance cannot be increased by increasing the width of the transistor. As a result, it is necessary to fabricate multiple nanotube FETS. This should result in an increase in transconductance, signal to noise ratio, and power handling capability.

Therefore, since it is desirable to fabricate carbon nanotube field effect transistors with multiple nanotubes forming the channel of the transistor, for nano RF applications for example, the presence of metallic nanotubes in the channel significantly reduces the ON/OFF ratio imposing a severe limitation on potential applications. Although it is easy to eliminate (burn off) metallic tubes in the channel of a backgated device by passing a large current through the channel while semiconducting nanotubes are turned off. However, this has proven difficult for top gated devices, especially if fabricated on a low-loss substrate such as quartz. An added difficulty in the case of structures with a dielectric along the entire length of the nanotube is that a top gate cannot be used for the electrical burn due to lack of oxygen needed in the burnout process. Therefore, an improved structure and method of fabricating a gated field effect transistor is needed for single semiconducting nanotube devices, multiple semiconducting nanotube devices, and multiple nanotube devices having both metallic and semiconducting nanotubes.

Accordingly, it is desirable to provide a multiple, independent top gated field effect transistor having an improved electron injection that suppresses the ambipolar transport characteristic of a Schottky barrier carbon nanotube field effect transistor and allows for the destruction of metallic carbon nanotubes positioned between the source and drain of a top multi-gate transistor. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A multiple, independent top gated field effect transistor and a method that allows for the destruction of metallic carbon nanotubes positioned between the source and drain of a top multi-gate transistor are provided. The field effect transistor comprises at least one carbon nanotubes coupled between the first and second electrodes and a first gate material formed over a portion of the at least one carbon nanotubes and spaced apart from the first and second electrodes. A dielectric material is conformally coated on the first and second electrodes, the at least one carbon nanotubes, and the first gate material. A second gate material is conformally coated on the dielectric material. Other exemplary embodiments include one gate, three gates, and three gates having the dielectric layer portioned with different material characteristics.

### BRIEF DESCRIPTION OF THE DRAWINGS

The present invention will hereinafter be described in conjunction with the following drawing figures, wherein like numerals denote like elements, and

FIG. 1 is a partial cross section of a field effect transistor;

FIG. 2 is a top view of the field effect transistor of FIG. 1;

FIGS. 3-5 are partial cross sections of fabrication steps for a first exemplary embodiment;

FIG. 6 is a partial cross section of a second embodiment;

FIG. 7 is a partial cross section of a third embodiment;

FIG. 8 is a partial cross section of a fourth embodiment;

FIG. 9 is a partial cross section of a fifth embodiment; and

FIG. 10 is a partial cross section of a sixth embodiment.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

One-dimensional nanostructures such as nanotubes and nanowires show promise for the development of molecular-scale sensors, resonators, field emission displays, and logic/memory elements. One-dimensional nanostructures are herein defined as a material having a high aspect ratio of greater than 10 to 1 (length to diameter).

In accordance with an exemplary embodiment, an under lapped top-gated field effect transistor is formed with one-dimensional nanostructures as the channel between the source and drain. Optionally, an electrical burn-out of any metallic one-dimensional nanostructures is performed by applying a current between the source and drain while applying a voltage to a first gate, wherein the first gate is formed over a first dielectric layer spaced between the source and drain. A second dielectric layer is conformally coated over the source, drain, one-dimensional nanostructures, first dielectric layer, and the first gate. A second gate is conformally coated over the second dielectric layer, providing a two gate structure comprising a first exemplary embodiment. An opening in the second dielectric layer may be etched to allow the second gate to contact the first gate, providing a single gate structure comprising a second exemplary embodiment. The second gate may define a gap over the first gate, providing a three gate structure (a third embodiment). Furthermore, the second dielectric layer may comprise different thicknesses or material characteristics between the source and the first gate, and between the drain and the first gate (a fourth embodiment).

This approach to fabricating a field effect transistor allows for electrical burning of metallic nanotubes, which is critical for many nanoRF applications, during the fabrication process. Additionally, this approach is easily integrated without damaging the nanotubes, and allows for flexibility of varying the gate dielectric material, thickness and/or metal gate work function for each of the three gate segments. This source-drain asymmetry improves performance by improving electron injection efficiency and reducing current when the transistor is off. A carbon nanotube field effect transistor having a geometry providing a large electric field at the source, but a small electric field at the drain, suppresses unwanted minority carrier injection.

Referring to FIG. 1, the structure 10 comprises a plurality of one-dimensional nanostructures 14 grown or placed on a substrate 12. Though the described exemplary embodiment comprises a plurality of one-dimensional nanostructures 14, it is understood that only one one-dimensional nanostructure 14 is an alternative embodiment. The substrate 12 comprises preferably silicon dioxide; however, alternate materials, for example, glass, ceramic, metal, quartz, sapphire, a semiconductor material, or a flexible material is anticipated by this disclosure. Substrate 12 can include control electronics or other circuitry, some of which may comprise circuitry (not shown). Also, substrate 12 may include an insulating layer, such as silicon dioxide, silicon nitride, or the like. One-dimensional nanostructures 14, which may be single walled or double-walled, extend from, and make electrical contact with source electrode 16 and drain electrode 18. The one-dimensional nanostructures 14 may comprise only a couple of one-dimensional nanostructures; however, since a single carbon nanotube 14 may suffer from device-to-device variation which limits the usability of the device, a plurality of carbon nanotubes 18 are positioned across the pair of electrodes 16 and 18 to minimize these issues. The nanotubes 14 may be grown, or previously grown and placed in a predefined position, in any manner known to those skilled in the art, and are typically 10 nm to 1 cm in length and less than 1 nm to 5 nm in diameter. Contact between the nanotubes 18 and electrodes 22 and 24 are made during fabrication, for example, by any type of lithography, e-beam, optical, soft lithography, or imprint technology. While the one-dimensional nanostructures 14 may comprise a mesh, it is preferred they comprise a plurality of one-dimensional nanostructures extending somewhat parallel between the source and drain electrodes without contacting adjacent one-dimensional nanostructures 14 (FIG. 2). Although some carbon nanotubes 14 may touch, even cross, other carbon nanotubes 18, each carbon nanotube 18 will extend from source electrode 16 to drain electrode 18. The one-dimensional nanostructures 14 may grow from a catalyst (not shown) or placed before or after the source and drain electrodes 16 and 18 are formed. The carbon nanotubes 18 are positioned below the electrodes 16 and 18 as shown, but alternatively some or all may be positioned above the electrodes 16 and 18. Lithographic masking and etching techniques may then used to remove the carbon nanotubes 14 not connected between source and drain electrodes 16 and 18.

The electrodes 16 and 18 comprise Cr/Au, but may comprise any conducting material including Ti/Au, Ti/Pd, and Pd. The electrodes 16 and 18 are preferably spaced between 10 nanometers and 1 millimeters apart. The thickness of the electrodes 14, 16 is generally between 0.01 and 100 micrometers, and would preferably be 1.0 micrometer.

A dielectric material 22 is formed by standard lithographic techniques, e.g., deposition, on the one-dimensional nanostructures 14 and a gate electrode 24 is formed thereover.

One-dimensional nanostructures 14 can function as either a conductor, or a semiconductor, according to the chirality and the diameter of the helical tubes. With metallic-like nanotubes, a one-dimensional carbon-based structure can conduct a current at room temperature with essentially no resistance. This is undesired when formed for the channel region of a field effect transistor. The exemplary embodiments of a top gated field effect transistor described below allows for removal, or burn-off, of metallic one-dimensional nanostructures formed along with the semiconductor one-dimensional nanostructures. Once the structure of FIG. 1 is completed, a voltage is applied to the gate electrode 24 to deplete semiconductor one-dimensional nanostructures of carriers. A voltage is applied across the source conductor 16 and drain conductor 18, wherein the resulting current flowing through the metallic one-dimensional nanostructures burns an opening therein.

At a current density greater than carbon nanotubes 14 can withstand, generally greater than 10⁹ A/cm² in an oxidizing environment, the carbon nanotubes will fail, or partially disintegrate, disrupting current flow. Applying a voltage to the gate 24, will selectively deplete carriers from the semiconducting nanotubes. When depleted, the semiconducting nanotubes will not fail; however, the current flowing through metallic nanotubes will cause them to fail, i.e., oxidize, since their carriers are not depleted. As current flows through the metallic nanotubes causing them to fail, the total current will drop. The current between the electrodes 16, 18 may be monitored and removed when a drop in current is noticed.

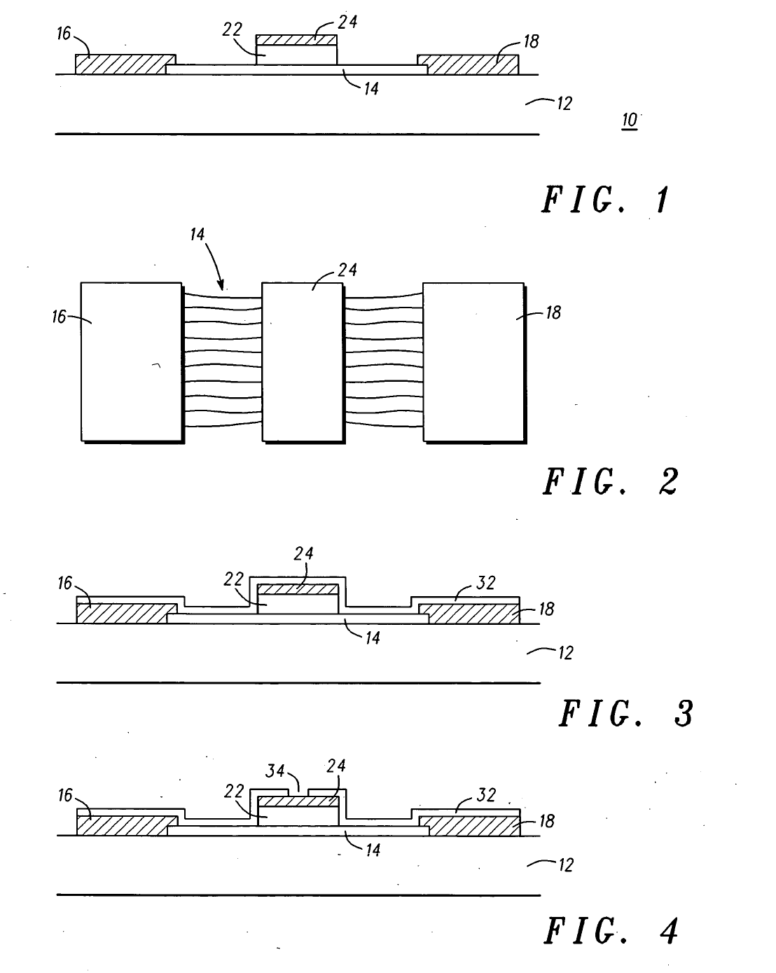

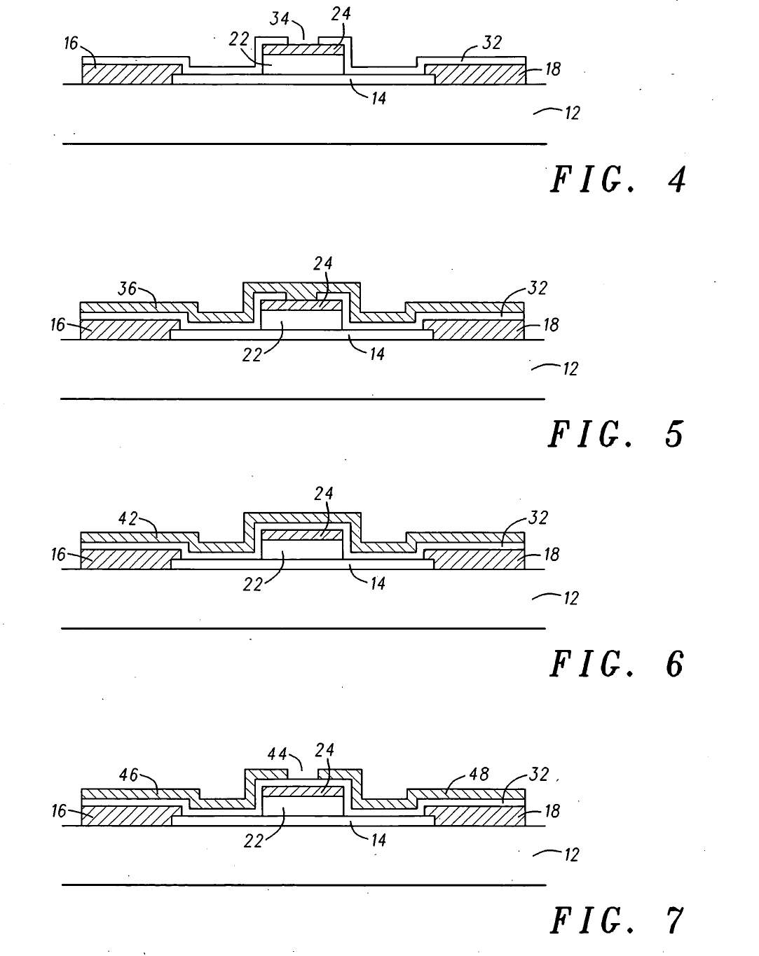

Referring to FIG. 3 and in accordance with a first exemplary embodiment, a dielectric layer 32 is conformally deposited over the surfaces of the source electrode 16, drain electrode 18, one-dimensional nanostructures 14, dielectric material 22 and gate electrode 24. The dielectric layer preferably comprises HfO₂, but may comprise any non-conductive material such as ZrO₂, Al₂O₃, SiO₂, and Si₃N₄. Using any known lithographic and etching techniques, a portion of the dielectric layer 32 over the gate electrode 24 is removed to form the opening 34 (FIG. 4). A gate electrode 42 of a conductive material is conformally deposited over the dielectric layer 32, including within the opening 34 and on the gate material 24 (FIG. 5). The resulting structure of FIG. 5 provides a single gate including gate electrode 24 and gate electrode 36 that provides improved electron injection.

A second exemplary embodiment is shown in FIG. 6 and comprises, after depositing the conformal dielectric layer 32 as shown in FIG. 3, conformally depositing the gate electrode 42 thereover. The resulting two gate structure, including gate electrodes 22 and 42 provides improved electron injection by applying different bias to the gates electrodes 22 and 42.

FIG. 7 illustrates a third exemplary embodiment. After depositing the conformal dielectric layer 32 as shown in FIG. 3, the gate electrode 42 of FIG. 6 is etched using known etching techniques to form the opening, or gap, 44, resulting in a three gate structure comprising the gate electrode 22, 46, and 48 provides improved electron injection at the source and reduced minority carrier injection at the drain by applying different biases to the three gates electodes 22, 46, and 48.

FIG. 8 illustrates a fourth exemplary embodiment, of a three gate device. After forming the structure 10 of FIG. 1, a dielectric layer 52 is deposited on the source electrode 16, one-dimensional nanostructures 14, and the gate electrode 24, and a gate electrode 54 is deposited thereon. A dielectric layer 56 is then deposited conformally over the drain electrode 18, the one-dimensional nanostructures 14, the dielectric material 22, and the gate electrode 24, and the gate electrode 58 is deposited thereon. A single bias may be applied to each of the gate electrodes 24, 54, and 58. The dielectric material 56 is thicker than the dielectric material 52, thereby providing an asymmetry resulting in a higher gate source bias which suppresses the Schottky contact between the one-dimensional nanostructures 13 and the source electrode 16, which results in an improved electron injection efficiency at the source and reduced minority carrier injection at the drain.

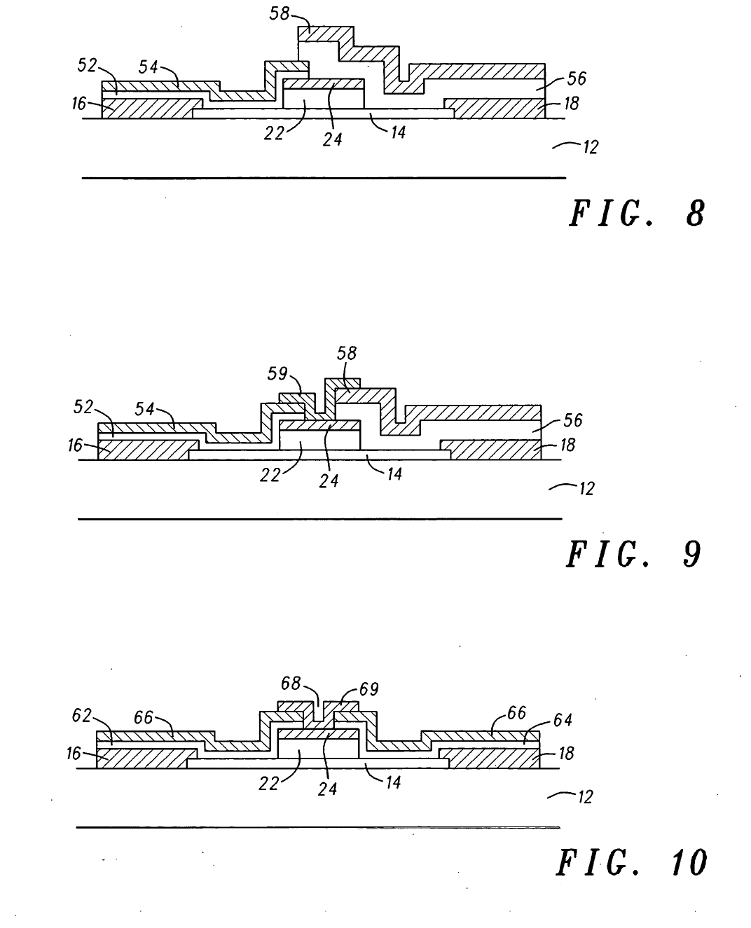

A variation of the fourth embodiment is shown in the fifth embodiment of FIG. 9 wherein the dielectric layer 56 and the gate electrode 58 do not overlap the dielectric layer 52 and the gate electrode 54. Gate electrodes 24, 54 and 58, or any combination thereof, may optionally be coupled (during processing), such as by gate electrode 59, to apply a single bias.

FIG. 10 is a sixth embodiment comprising a first dielectric material 62 formed over the source electrode 16, the one-dimensional nanostructures 14, the dielectric material 22, and gate electrode 24. A second dielectric material 64 is formed over the drain electrode 18, the one-dimensional nanostructures 14, the dielectric material 22, and gate electrode 24. The metal 66 is then deposited on both the first and second dielectric material 62 and 64 and etched to form an opening 68 so that a first portion 72 of the metal 66 is positioned over the first dielectric material 62 and a second portion 74 of the metal 66 is positioned over the second dielectric material 64. The extension of the opening 68 between the first and second dielectric layers 62 and 64 is optional. The first dielectric material 62 and the second dielectric material 64 comprise different high-k constants, thereby providing an asymmetry resulting in a higher gate source bias which suppresses the Schottky barrier between the one-dimensional nanostructures 13 and the source electrode 16, which results in an improved electron injection efficiency. The second gate dielectric 64 with a relatively lower dielectric constant is used to reduce drain bias induced minority carrier injection. Gate electrodes 24 and 66 may optionally be coupled (during processing), such as by gate electrode 69, to apply a single bias.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method of fabricating a field effect transistor, comprising:
providing a substrate;
forming a source electrode on the substrate;
forming a drain electrode on the substrate and spaced from the source electrode;
providing at least one one-dimensional nanostructure over the substrate and coupled between the source and drain electrodes, wherein the at least one one-dimensional nanostructure includes at least one semiconductor one-dimensional nanostructure;
forming a first dielectric material on a portion of the at least one one-dimensional nanostructure and spaced apart from the source and drain electrodes;
forming a first gate material over the first dielectric material;
conformally coating a second dielectric material on the source and drain electrodes, the at least one one-dimensional nanostructures, and the first dielectric and first gate material; and
conformally coating a second gate material on the second dielectric material.

2. The method of claim 1 wherein the conformally coating a second dielectric material includes defining an opening in the second dielectric material over the first gate material, and wherein the conformally coating a second gate material includes forming the second gate material to contact the first gate material through the opening.

3. The method of claim 1 wherein the conformally coating a second gate material includes defining a gap in the second gate material over the first gate material, and wherein the conformally coating the second gate material over the source electrode comprises a third gate material and the second gate material over the drain electrode comprises a fourth gate material.

4. The method of claim 3 wherein the method further comprises forming a fifth gate material coupled to each of the first, third, and fourth gate material.

5. The method of claim 3 wherein the conformally coating a second dielectric material comprises:
forming a third dielectric material between the third gate material and the source electrode, a portion of the plurality of one-dimensional nanostructures, and the first gate material; and
forming a fourth dielectric material between the fourth gate material and the drain electrode, a portion of the plurality of one-dimensional nanostructures, and the first gate material, wherein the third and fourth dielectric material have different thicknesses.

6. The method of claim 3 wherein the conformally coating a second dielectric material comprises:
forming a third dielectric material between the third gate material and the source electrode, a portion of the plurality of one-dimensional nanostructures, and the first gate material; and
forming a fourth dielectric material between the fourth gate material and the drain electrode, a portion of the plurality of one-dimensional nanostructures, and the first gate material, wherein the third and fourth dielectric material have different material characteristics.

7. The method of claim 1, wherein the at least one one-dimensional nanostructure further comprises at least one metallic one-dimensional nanostructure, and before conformally coating a second dielectric material, further comprising:
applying a voltage to the first gate material; and
applying a voltage between the source and drain electrodes to burn through the at least one metallic one-dimensional nanostructures.

8. The method of claim 2, wherein the at least one one-dimensional nanostructure further comprises at least one metallic one-dimensional nanostructure, and before conformally coating a second dielectric material, further comprising:
applying a voltage to the first gate material; and
applying a voltage between the source and drain electrodes to burn through the at least one metallic one-dimensional nanostructures.

9. The method of claim 3, wherein the at least one one-dimensional nanostructure further comprises at least one metallic one-dimensional nanostructure, and before conformally coating a second dielectric material, further comprising:
applying a voltage to the first gate material; and
applying a voltage between the source and drain electrodes to burn through the at least one metallic one-dimensional nanostructures.

10. The method of claim 5, wherein the at least one one-dimensional nanostructure further comprises at least one metallic one-dimensional nanostructure, and before conformally coating a second dielectric material, further comprising:
applying a voltage to the first gate material; and
applying a voltage between the source and drain electrodes to burn through the at least one metallic one-dimensional nanostructures.

11. The method of claim 6, wherein the at least one one-dimensional nanostructure further comprises at least one metallic one-dimensional nanostructure, and before conformally coating a second dielectric material, further comprising:
applying a voltage to the first gate material; and
applying a voltage between the source and drain electrodes to burn through the at least one metallic one-dimensional nanostructures.

12. A field effect transistor, comprising:
a first electrode;
a second electrode;
a plurality of semiconducting carbon nanotubes coupled between the first and second electrodes;
a first gate material formed over a portion of the plurality of semiconducting carbon nanotubes and spaced apart from the first and second electrodes;
a first dielectric material conformally coated on the first and second electrodes; the plurality of semiconducting carbon nanotubes, and the first gate material; and
a second gate material conformally coated on the first dielectric material.

13. The field effect transistor of claim 12 wherein the first dielectric material includes an opening defined in the first dielectric material over the first gate material, and wherein the second gate material contacts the first gate material through the opening.

14. The field effect transistor of claim 12 wherein the second gate material defines a gap in the second gate material over the first gate material, and wherein the second gate material over the first electrode, the plurality of semiconducting carbon nanotubes, and first gate material comprises a third gate material, and the second gate material over the second electrode, the plurality of semiconducting carbon nanotubes, and the first gate material comprises a fourth gate material.

15. The field effect transistor of claim 14 wherein the first, third, and fourth gate material are coupled together.

16. The field effect transistor of claim 14 wherein the conformally coating a first dielectric material comprises forming a second dielectric material between the third gate material and the first electrode, a portion of the plurality of semiconducting carbon nanotubes, and the first gate material, and a third dielectric material between the fourth gate material and the second electrode, a portion of the plurality of semiconducting carbon nanotubes, and the first gate material, wherein the second and third dielectric material have different thicknesses.

17. The field effect transistor of claim 14 wherein the conformally coating a first dielectric material comprises forming a second dielectric material between the third gate material and the first electrode, a portion of the plurality of semiconducting carbon nanotubes, and the first gate material, and a third dielectric material between the fourth gate material and the second electrode, a portion of the plurality of semiconducting carbon nanotubes, and the first gate material, wherein the second and third dielectric material have different material characteristics.

18. A field effect transistor, comprising:
a substrate;
a source electrode formed over a first portion of the substrate;
a drain electrode formed over a second portion of the substrate and spaced from the source electrode;
a plurality of semiconductor carbon nanotubes provided over the substrate and coupled between the source and drain electrodes;
a first dielectric material formed on a portion of the plurality of semiconductor carbon nanotubes and spaced apart from the source and drain electrodes;
a first gate material formed over the first dielectric material;
a second dielectric material conformally coated on the source and drain electrodes; the plurality of semiconductor carbon nanotubes, and the first dielectric and first gate material; and
a second gate material conformally coated on the second dielectric material.

19. The field effect transistor of claim 18 wherein the second dielectric material includes an opening defined in the second dielectric material over the first gate material, and wherein the second gate material contacts the first gate material through the opening.

20. The field effect transistor of claim 18 wherein the second gate material defines a gap in the second gate material over the first gate material, and wherein the second gate material over the source electrode, the plurality of carbon nanotubes, the first dielectric, and first gate material comprises a third gate material and the second gate material over the drain electrode, the plurality of carbon nanotubes, the first dielectric, and first gate material comprises a fourth gate material.

21. The field effect transistor of claim 20 wherein the conformally coating a second dielectric material comprises forming a third dielectric material between the third gate material and the source electrode, a portion of the plurality of carbon nanotubes, and the first gate material, and a fourth dielectric material between the fourth gate material and the drain electrode, a portion of the plurality of carbon nanotubes, and the first gate material, wherein the third and fourth dielectric material have different thicknesses.

22. The field effect transistor of claim 20 wherein the conformally coating a second dielectric material comprises forming a third dielectric material between the third gate material and the source electrode, a portion of the plurality of carbon nanotubes, and the first gate material, and a fourth dielectric material between the fourth gate material and the drain electrode, a portion of the plurality of carbon nanotubes, and the first gate material, wherein the third and fourth dielectric material have different material characteristics.
